(19) United States
(12) Patent Application Publication
(10) Pub. No.: US 2014/0332940 A1
(43) Pub. Date: Nov. 13, 2014

(54) Quad Flat No-Lead Integrated Circuit Package and Method for Manufacturing the Package

(71) Applicant: STS SEMICONDUCTOR & TELECOMMUNICATIONS CO., LTD., Cheonan-si (KR)

(72) Inventor: Jong Myoung SON, Cheonan-si (KR)

(21) Appl. No.: 13/932,796

(22) Filed: Jul. 1, 2013

(30) Foreign Application Priority Data
May 7, 2013 (KR) 10-2013-0051247

(51) Int. Cl. H01L 23/495; H01L 23/00

(52) U.S. Cl. CPC H01L 23/49575; H01L 24/81
USPC 257/673; 438/123

(57) ABSTRACT

A quad flat no-lead (QFN) integrated circuit package is provided.

The QFN integrated circuit package includes an insulating adhesive layer, a semiconductor chip attached to the insulating adhesive layer, and a lead frame bent to be electrically connected to the semiconductor chip and attached to the insulating adhesive layer.

The QFN integrated circuit package according the present invention does not use a die paddle and is thus thin. Accordingly, the volume of the package can be minimized.

### BACKGROUND OF THE INVENTION

1. Field of the Invention

The present invention relates to an integrated circuit package and a method for manufacturing the same, and more particularly to a quad flat no lead (QFN) integrated circuit package and a method for manufacturing the same.

2. Description of the Related Art

Electronic appliances such as personal computers, cellular phones and camcorders have recently sought compact size and high processing capacity. As such, semiconductor packages are required to have compact size, high capacity, and high processing speed. Accordingly, development of semiconductor packages is quickly turning from conventional insert-mount type packages such as dual in-line (DIP) packages to surface-mount type packages such as quad flat no-leads (QFNs), thin small-outline packages (TSOPs), thin quad flat packages (TQFPs), and ball grid arrays (BGAs).

Among surface-mount type packages, the QFN package uses a lead frame as in common semiconductor packages, but the size and weight thereof can be remarkably reduced. In addition, QFN packages are drawing attention due to high quality and high reliability thereof.

FIG. 1 is a cross-sectional view showing the structure of a conventional quad flat no lead (QFN) integrated circuit package.

Referring to FIG. 1, the conventional QFN integrated circuit package has a structure in which a semiconductor chip 30 is mounted on a lead 10 and a paddle 20, which are at an upper portion of a lead frame, and sealed by an epoxy molding compound (EMC) 40. Generally, the semiconductor chip 30 is attached to the lead 10 and the paddle 20 through flip-chip bonding, and the lower surface of the paddle 20 is soldered to a printed circuit board (not shown).

However, with increased demand for slim and lightweight design and simplicity of electronic appliances, efforts are continuously put forth to further reduce thickness and weight of an integrated circuit package.

### SUMMARY OF THE INVENTION

Therefore, the present invention has been made in view of the above problems, and it is an object of the present invention to provide a quad flat no-lead (QFN) integrated circuit package which can substantially address various problems caused by limitations and disadvantages of the conventional technology and a method for manufacturing the same.

It is another object of the present invention to provide a QFN integrated circuit package having a structure which does not use a die paddle and a method for manufacturing the same.

In accordance with an aspect of the present invention, the above and other objects can be accomplished by the provision of a quad flat no-lead (QFN) integrated circuit package including an insulating adhesive layer, a semiconductor chip attached to the insulating adhesive layer, and a lead frame bent to be electrically connected to the semiconductor chip and attached to the insulating adhesive layer.

The semiconductor chip may be provided with a non-active surface to be attached to the insulating adhesive layer, and an active surface facing the non-active surface and having a solder ball at an edge thereof, wherein the lead frame may be electrically connected to the semiconductor chip via the solder ball.

The insulating adhesive layer may be a tape-shaped adhesive layer configured with a polyimide tape.

In accordance with another aspect of the present invention, there is provided a method for manufacturing a quad flat no-lead (QFN) integrated circuit package including preparing a plurality of semiconductor chips, each of the semiconductor chips being provided with a solder ball at an edge of an active surface thereof, attaching an insulating tape to a carrier, aligning the semiconductor chips on the insulating tape and attaching the semiconductor chips to the insulating tape such that a non-active surface of each of the semiconductor chips facing the active surface is attached to the insulating tape, and forming a lead frame bent to be electrically connected to the semiconductor chips via the solder ball and attached to the insulating tape.

In the method, the insulating tape is formed by a polyimide tape.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a cross-sectional view showing the structure of a conventional quad flat no-lead (QFN) integrated circuit package;

FIG. 2 is a cross-sectional view showing the structure of a QFN integrated circuit package according to an exemplary embodiment of the present invention; and

FIGS. 3A to 3C are views illustrating the processes of manufacturing a stacked semiconductor package according to an embodiment of the present invention.

### DETAILED DESCRIPTION OF THE INVENTION

Reference will now be made in detail to embodiments of the present invention, examples of which are illustrated in the accompanying drawings.

In describing the present invention, a detailed description of well-known functions and constituents will be omitted if such description could unnecessarily obscure the main points of the present invention. In addition, terms which will be used below are defined in consideration of the functions of the present invention. The definitions of the terms may vary depending on intention of a user or a precedent case. Therefore, the terms should be defined based on the entire specification.

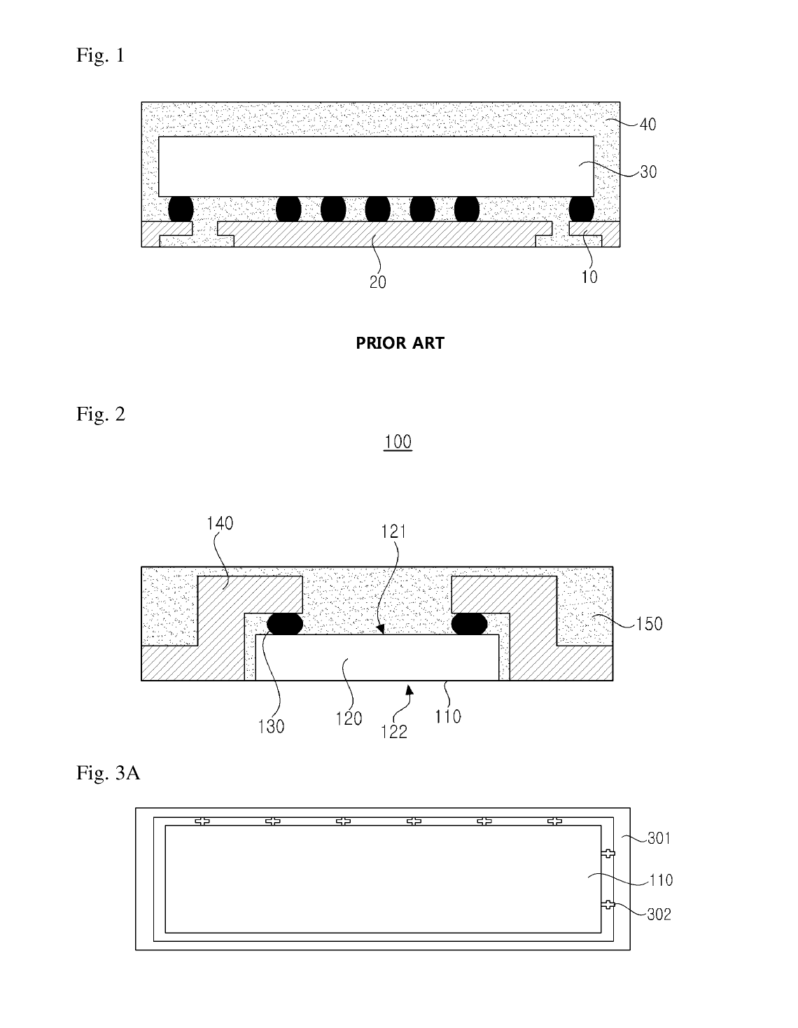

FIG. 2 is a cross-sectional view showing the structure of a quad flat no-lead (QFN) integrated circuit package according to an exemplary embodiment of the present invention.

Referring to FIG. 2, the QFN integrated circuit package 100 includes an insulating tape 110, a semiconductor chip 120 attached to the insulating tape 110, a solder ball 130 formed on the semiconductor chip 120, a lead frame 140 connected to the semiconductor chip 120 via the solder ball 130, and an encapsulant 150 surrounding the semiconductor chip 120 and the lead frame 140.

The insulating tape 110 is, for example, a polyimide tape. Since the polyimide tape has good mechanical properties and good heat resistance, exhibits good insulation at high temperature, and has high reliability, it is widely used throughout the electronics industry.

The semiconductor chip 120 may include a large scale integrated circuit semiconductor memory device such as a dynamic random access memory (DRAM), a static random access memory (SRAM) and a flash memory, a processor such as a central processing unit (CPU), digital signal processor (DSP) and a combination of a CPU and a DSP, and an individual semiconductor device configuring an application specific integrated circuit (ASIC), a microelectromechanical system (MEMS) device and an optoelectronic device. The semiconductor chip 120 can be prepared by forming individual semiconductor devices on a semiconductor wafer, backgrinding (or back lapping) the semiconductor wafer, and then separating the chip from the wafer. The semiconductor chip 120 may be provided with a first surface 121, which is an active surface having individual semiconductor devices formed thereon, and a second surface 122 facing the first surface 121. The second surface 122 is attached to the insulating tape 110.

The solder ball 130 is provided to electrically connect the semiconductor chip 120 to the lead frame 140. The solder ball 130 is preferably formed at the edge of the semiconductor chip 120.

The lead frame 140 may be formed of a material such as, for example, copper, nickel, other metals and metal alloys exhibiting good electrical and thermal conductivity.

An encapsulant suitable for the encapsulant 150 is a molded underfill (MUF) encapsulant which functions not only to fill the space between the semiconductor chip 120 and the lead frame 140, but also to seal the integrated circuit package 100. Such a MUF encapsulant allows the molding process to be performed without separately performing the underfill process, and uses an epoxy molding compound (EMC) whose reliability has been verified. Therefore, using the MUF encapsulant can simplify the processes.

The QFN integrated circuit package of the illustrated embodiment having the structure described above does not use a die paddle, and therefore thickness of the integrated circuit package can be reduced.

In addition, since the lower surface of the semiconductor chip is not sealed by the encapsulant, heat dissipation can be improved.

Further, since a common die bonder can be used in place of a flip chip bonder dedicated to flip chip bonding, equipment utilization can be increased.

A method for manufacturing a QFN integrated circuit package configured as above is described below.

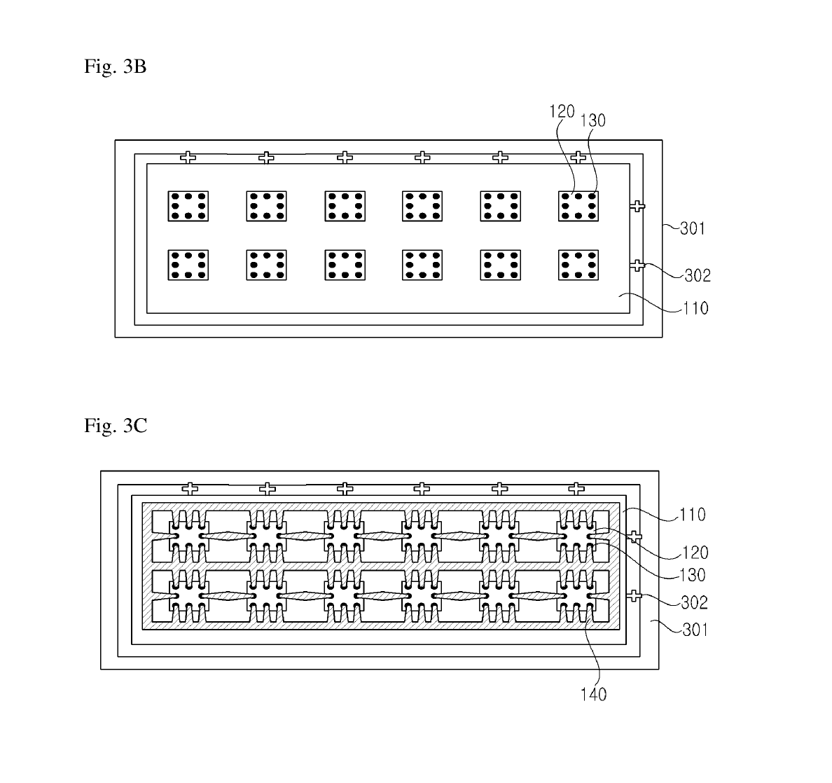

FIGS. 3A to 3C are views illustrating the processes of manufacturing a QFN integrated circuit package according to an embodiment of the present invention.

As shown in FIG. 3A, the insulating tape 110 is first prepared. In the illustrated embodiment, a polyimide tape is used as the insulating tape 110. For easy handling of the polyimide tape, the polyimide tape is placed on a carrier 301. In addition, an alignment key 302 to align the semiconductor chips is inserted into the carrier 301.

Next, as shown in FIG. 3B, the semiconductor chips 120 are placed on and attached to the insulating tape 110. At this time, the alignment key 302 on the carrier 301 is utilized to align and attach a plurality of semiconductor chips 120 to the insulating tape 110 such that non-active surfaces of the semiconductor chips 120 are attached to the insulating tape 110. The solder balls 130 are formed on the active surface facing the non-active surfaces of the semiconductor chips 120. That is, the semiconductor chips 120 are electrically connected to the lead frame 140 by flip chip bonding, with the semiconductor chip 120 facing upward.

Next, as shown in FIG. 3C, the lead frame 140 is placed on and attached to the semiconductor chips 120 and the insulating tape 110. At this time, the lead frame 140 can be attached in bulk or unit by unit. The lead frame 140 is electrically connected to the semiconductor chips 120 via a conductive bump 130.

Next, molding may be performed on the entire upper surface of the insulating tape 110 using the encapsulant 150 to seal the semiconductor chip 120 and the lead frame 140, which is not shown. The encapsulant may be configured with at least one of epoxy resin, silicone resin and equivalents thereof.

The method for manufacturing the QFN integrated circuit package of the illustrated embodiment as described above can not only reduce the height of the package compared to a conventional technique of manufacturing a package by mounting semiconductor chips on a die paddle, but also improve heat dissipation by exposing the semiconductor chips to the outside.

As is apparent from the above description, a QFN integrated circuit package according the present invention does not use a die paddle and is thus thin. Accordingly, the volume of the package can be minimized.

In addition, the lower surface of each semiconductor chip is not sealed by an encapsulant, and therefore heat dissipation can be improved.

Moreover, since a common die bonder can be used in place of a flip chip bonder dedicated to flip chip bonding, equipment utilization can be increased.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A quad flat no-lead (QFN) integrated circuit package comprising:
an insulating adhesive layer;
a semiconductor chip attached to the insulating adhesive layer; and
a lead frame bent to be electrically connected to the semiconductor chip and attached to the insulating adhesive layer.

2. The QFN integrated circuit package according to claim 1, wherein the semiconductor chip is provided with a non-active surface to be attached to the insulating adhesive layer, and an active surface facing the non-active surface and having a solder ball at an edge thereof,
wherein the lead frame is electrically connected to the semiconductor chip via the solder ball.

3. The QFN integrated circuit package according to claim 1, wherein the insulating adhesive layer is a tape-shaped adhesive layer configured with a polyimide tape.

4. A method for manufacturing a quad flat no-lead (QFN) integrated circuit package comprising:
preparing a plurality of semiconductor chips, each of the semiconductor chips being provided with a solder ball at an edge of an active surface thereof;
attaching an insulating tape to a carrier;
aligning the semiconductor chips on the insulating tape and attaching the semiconductor chips to the insulating tape such that a non-active surface of each of the semiconductor chips facing the active surface is attached to the insulating tape; and
forming a lead frame bent to be electrically connected to the semiconductor chips via the solder ball and attached to the insulating tape.

5. The method according to claim 4, wherein the insulating tape is formed by a polyimide tape.
